(19) United States
(12) Patent Application Publication
(10) Pub. No.: US 2011/0097875 A1
(43) Pub. Date: Apr. 28, 2011

(54) WAFER PROCESSING METHOD

(75) Inventors: Yohei Gokita, Ota-Ku (JP); Takashi Yamaguchi, Ota-ku (JP); Masashi Koyama, Ota-ku (JP); Masashi Aoki, Ota-ku (JP); Masaaki Suzuki, Ota-ku (JP); Katsuhiko Sekiya, Ota-ku (JP); Ye Chen, Ota-ku (JP); Keiichi Kajiyama, Ota-ku (JP); Toshiharu Daii, Ota-ku (JP)

(73) Assignee: DISCO CORPORATION, Tokyo (JP)

(21) Appl. No.: 12/909,078

(22) Filed: Oct. 21, 2010

(30) Foreign Application Priority Data
Oct. 26, 2009 (JP) 2009-245219

(51) Int. Cl. H01L 21/78

(52) U.S. Cl. 438/462; 257/E21.599

(57) ABSTRACT

A wafer processing method for dividing a wafer into individual devices along a plurality of crossing streets formed on the front side of the wafer, the individual devices being respectively formed in a plurality of regions partitioned by the streets. The wafer processing method includes the steps of attaching the front side of the wafer to a dicing tape supported to an annular dicing frame, grinding the back side of the wafer to reduce the thickness of the wafer to a predetermined thickness, forming a break start point along each street from the back side of the wafer, applying an external force to the wafer to break the wafer along each street where the break start point is formed, thereby dividing the wafer into the individual devices, attaching the back side of the wafer to a front side of an adhesive tape supported to an annular frame and next removing the adhesive tape from the front side of the adhesive tape, and peeling off and picking up each device from the adhesive tape.

### BACKGROUND OF THE INVENTION

1. Field of the Invention

The present invention relates to a wafer processing method for dividing a wafer into individual devices along a plurality of crossing streets formed on the front side of the wafer, the individual devices being respectively formed in a plurality of regions partitioned by the streets.

2. Description of the Related Art

In a semiconductor device fabrication process, a plurality of crossing division lines called streets are formed on the front side of a substantially disk-shaped semiconductor wafer to thereby partition a plurality of regions where devices such as ICs and LSIs are respectively formed. The semiconductor wafer is cut along the streets to thereby divide the regions where the devices are formed from each other, thus obtaining the individual devices. Further, an optical device wafer is formed by laminating gallium nitride compound semiconductors or the like on a sapphire substrate or a silicon carbide substrate. The optical device wafer is also cut along the streets to obtain individual optical devices divided from each other, such as light emitting diodes and laser diodes, which are widely used in electric equipments.

Cutting of such a wafer including a semiconductor wafer and an optical device wafer along the streets is usually performed by using a cutting apparatus called a dicer. This cutting apparatus includes a chuck table for holding a workpiece such as a semiconductor wafer and an optical device wafer, cutting means for cutting the workpiece held on the chuck table, and feeding means for relatively moving the chuck table and the cutting means. The cutting means includes a rotating spindle, a cutting blade mounted on the rotating spindle, and a driving mechanism for rotationally driving the rotating spindle. The cutting blade is composed of a disk-shaped base and an annular cutting edge mounted on a side surface of the base along the outer circumference thereof. The cutting edge is formed by fixing diamond abrasive grains having a grain size of about 3 μm to the base by electroforming so that the thickness of the cutting edge becomes about 20 μm, for example.

However, the sapphire substrate and the silicon carbide substrate mentioned above have high Mohs hardness, so that cutting by the cutting blade is not always easy.

Further, since the cutting blade has a thickness of about 20 μm, each street partitioning the devices must have a width of about 50 μm. As a result, the ratio in area of the streets to the wafer is increased, causing a reduction in productivity.

As a method of dividing a wafer along the streets, a laser processing method using a pulsed laser beam having a transmission wavelength to the wafer has been proposed. In this laser processing method, the pulsed laser beam is applied to the wafer along the streets in the condition where a focal point of the pulsed laser beam is set inside the wafer, thereby continuously forming a modified layer inside the wafer along each street as a break start point. Thereafter, an external force is applied to the wafer along each street where the modified layer is formed as the break start point, thereby breaking the wafer along each street (see Japanese Patent No. 3408805, for example).

As another method of dividing a wafer along the streets, a laser processing method using a pulsed laser beam having an absorption wavelength to the wafer has been proposed. In this laser processing method, the pulsed laser beam is applied to the wafer along the streets to thereby form a laser processed groove on the wafer along each street as a break start point. Thereafter, an external force is applied to the wafer along each street where the laser processed groove is formed as the break start point, thereby breaking the wafer along each street (see Japanese Patent Laid-Open No Hei 10-305420, for example).

As another method of dividing a wafer along the streets, a method using a diamond scriber to form a scribe groove on the front side of the wafer along each street as a break start point has also been put to practical use. After forming the scribe groove along each street, an external force is applied to the wafer along each street where the scribe groove is formed as the break start point, thereby breaking the wafer along each street.

In these wafer dividing methods, the back side of the wafer is first ground to reduce the thickness of the wafer to a predetermined thickness. In performing this grinding step, a protective member is attached to the front side of the wafer to protect the devices formed on the front side of the wafer. Thereafter, the wafer is processed to form the modified layer, the laser processed groove, or the scribe groove as the break start point along each street. In applying an external force to the wafer along each street where the modified layer, the laser processed groove, or the scribe groove is formed as the break start point to thereby break the wafer along each street, the back side of the wafer is attached to a front side of a dicing tape supported to an annular frame, and the protective member is removed from the front side of the wafer. However, in removing the protective member from the front side of the wafer, there occurs a problem of cracking in the wafer.

To solve such a problem, Japanese Patent Laid-Open No. 2005-222988 discloses a wafer dividing method including a back grinding step of grinding the back side of a wafer to reduce the thickness of the wafer to a predetermined thickness, a modified layer forming step of applying a laser beam having a transmission wavelength to the wafer along the streets to thereby form a modified layer inside the wafer along each street, and a dividing step of applying an external force to the wafer along each street where the modified layer is formed, thereby dividing the wafer along each street into individual devices, wherein the back grinding step, the modified layer forming step, and the dividing step are performed in the condition where the front side of the wafer is attached to a dicing tape supported to an annular frame.

### SUMMARY OF THE INVENTION

According to the method disclosed in Japanese Patent Laid-Open No. 2005-222988, the back grinding step, the modified layer forming step, and the dividing step are performed in the condition where the front side of the wafer is attached to the dicing tape supported to the annular frame. After performing the dividing step, each device is peeled off and picked up from the dicing tape. At this time, each device is pushed up by a push pin from the lower side (back side) of the dicing tape. Accordingly, the front side of each device is pushed up through the dicing tape by the push pin, so that there is a problem of damage to the front side of each device by the push pin. Further, in this pickup step, the back side of each device is held and picked up, so that it is necessary to reverse each device in the subsequent step.

It is therefore an object of the present invention to provide a wafer processing method which can divide a wafer into individual devices without cracking in the wafer after grinding the back side of the wafer to reduce the thickness of the wafer to a predetermined thickness and can pick up each device without damage to the front side of each device after dividing the wafer into the individual devices.

In accordance with an aspect of the present invention, there is provided a wafer processing method for dividing a wafer into individual devices along a plurality of crossing streets formed on the front side of the wafer, the individual devices being respectively formed in a plurality of regions partitioned by the streets, the wafer processing method including a wafer supporting step of attaching the front side of the wafer to a dicing tape supported to an annular dicing frame; a back grinding step of grinding the back side of the wafer to reduce the thickness of the wafer to a predetermined thickness after performing the wafer supporting step; a break start point forming step of forming a break start point along each street from the back side of the wafer after performing the back grinding step; a wafer breaking step of applying an external force to the wafer to break the wafer along each street where the break start point is formed, thereby dividing the wafer into the individual devices after performing the break start point forming step; a wafer transferring step of attaching the back side of the wafer to an adhesive tape supported to an annular frame and next peeling off the dicing tape from the front side of the wafer to remove the annular dicing frame after performing the wafer breaking step; and a pickup step of peeling off and picking up each device from the adhesive tape after performing the wafer transferring step.

Preferably, the wafer processing method further includes a back polishing step of polishing the back side of the wafer by using a polishing pad after performing the back grinding step and before performing the break start point forming step.

According to the present invention, the back grinding step of grinding the back side of the wafer to reduce the thickness of the wafer to a predetermined thickness, the break start point forming step of forming a break start point along each street from the back side of the wafer, and the wafer breaking step of applying an external force to the wafer to break the wafer along each street where the break start point is formed, thereby dividing the wafer into the individual devices are performed in the condition where the front side of the wafer is attached to the dicing tape supported to the annular dicing frame. Thereafter, the wafer transferring step of attaching the back side of the wafer to the front side of the adhesive tape supported to the annular frame and next removing the dicing tape from the front side of the wafer is performed to thereby transfer the wafer from the dicing tape to the adhesive tape in the condition where the wafer has already been divided into the individual devices. Accordingly, the wafer can be reversed without cracking in the wafer.

Accordingly, a continuity test can be performed for each device in the condition where the wafer divided into the individual devices is attached to the adhesive tape supported to the annular frame. Further, in the case that each device is pushed up by a push pin from the lower side of the adhesive tape in the pickup step, the back side of each device is pushed up by the push pin through the adhesive tape. Accordingly, the damage to the front side of each device by the push pin can be prevented. Further, the back side of each device is attached to the adhesive tape in the wafer transferring step, and the front side of each device is held under suction and picked up in the pickup step. Accordingly, it is not necessary to reverse each device in the subsequent step.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of an optical device wafer as a wafer;

FIG. 2 is a perspective view of the wafer in the condition where the front side of the wafer is attached to a dicing tape supported to an annular dicing frame by performing a wafer supporting step;

FIG. 3 is a sectional side view showing a back grinding step;

FIG. 4 is a sectional side view showing a back polishing step;

FIG. 5 is a perspective view of an essential part of a laser processing apparatus for performing a modified layer forming step as an example of a break start point forming step;

FIGS. 6A and 6B are sectional side views for illustrating the modified layer forming step performed by the laser processing apparatus shown in FIG. 5;

FIG. 7 is a perspective view of a wafer breaking apparatus for performing a wafer breaking step;

FIGS. 8A and 8B are sectional side views for illustrating the wafer breaking step performed by the wafer breaking apparatus shown in FIG. 7;

FIGS. 9A to 9C are sectional side views for illustrating a wafer transferring step;

FIG. 9D is a perspective view of the wafer in the condition where the back side of the wafer is attached to an adhesive tape supported to an annular frame by performing the wafer transferring step shown in FIGS. 9A to 9C;

FIG. 10 is a perspective view of a pickup apparatus for performing a pickup step; and

FIGS. 11A and 11B are sectional side views for illustrating the pickup step performed by the pickup apparatus shown in FIG. 10

### DETAILED DESCRIPTION OF THE PREFERRED EMBODIMENTS

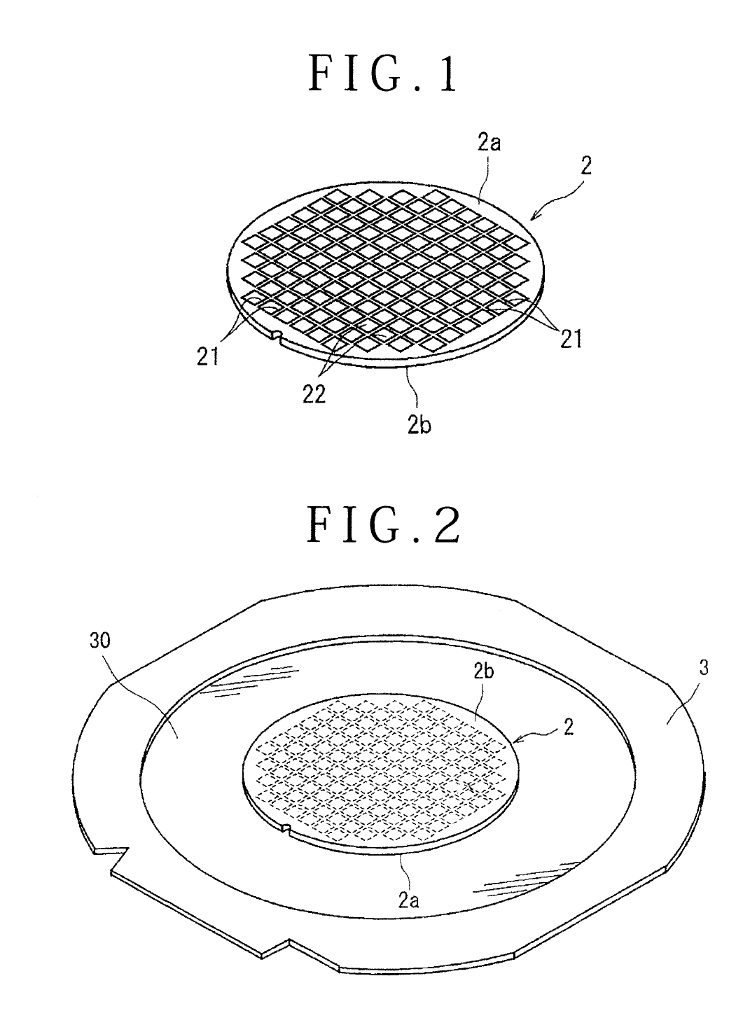

A preferred embodiment of the wafer processing method according to the present invention will now be described in detail with reference to the attached drawings. FIG. 1 is a perspective view of an optical device wafer 2 as a wafer. The optical device wafer 2 shown in FIG. 1 is formed from a sapphire wafer having a thickness of 600 μm, for example. The optical device wafer 2 has a front side 2a and a back side 2b. A plurality of crossing streets 21 are formed on the front side 2a of the optical device wafer 2 to thereby partition a plurality of rectangular regions where a plurality of optical devices 22 such as light emitting diodes and laser diodes are respectively formed. These optical devices 22 are formed by laminating gallium nitride compound semiconductors or the like. There will now be described a wafer processing method for dividing the optical device wafer 2 into the individual optical devices 22 along the streets 21.

First, a wafer supporting step is performed in such a manner that the front side 2a of the wafer 2 is attached to a dicing tape 30 supported to an annular dicing frame 3 as shown in FIG. 2. More specifically, the annular dicing frame 3 is formed of metal and the dicing tape 30 is preliminarily supported at its outer circumferential portion to the annular dicing frame 3. The front side 2a of the wafer 2 is attached to the front side of the dicing tape 30 (upper surface as viewed in FIG. 2). The dicing tape 30 is composed of a base sheet and an adhesive layer formed on the front side of the base sheet. The base sheet is formed of polyvinyl chloride (PVC) and has a thickness of 100 μm. The adhesive layer is formed of acrylic resin and has a thickness of about 5 μm. This adhesive layer has a property such that its adhesive strength is reduced by applying ultraviolet radiation.

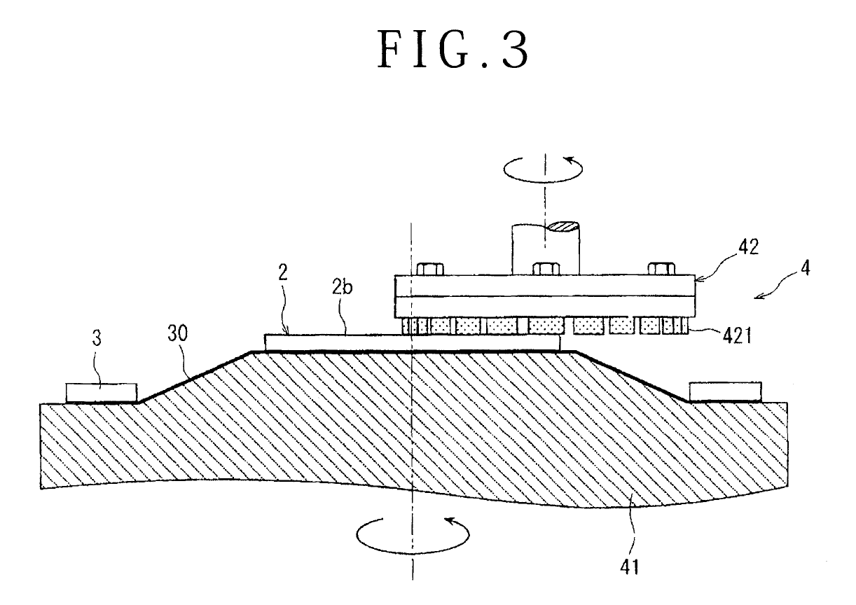

After performing the wafer supporting step mentioned above, a back grinding step is performed in such a manner that the back side 2b of the wafer 2 is ground to reduce the thickness of the wafer 2 to a predetermined thickness as shown in FIG. 3. This back grinding step is performed by using a grinding apparatus 4 shown in FIG. 3. The grinding apparatus 4 shown in FIG. 3 includes a chuck table 41 for holding the wafer 2 and a grinding tool 42 having a grinding wheel 421 for grinding the back side 2b of the wafer 2 held on the chuck table 41. The central portion adapted to hold the wafer 2 is higher in level than the peripheral portion adapted to hold the annular dicing frame 3.

The back grinding step using the grinding apparatus 4 is performed in the following manner. As shown in FIG. 3, the wafer 2 supported through the dicing tape 30 to the annular dicing frame 3 is placed on the holding surface of the chuck table 41 of the grinding apparatus 4 in the condition where the back side of the dicing tape 30 comes into contact with the holding surface of the chuck table 41. In this condition, the wafer 2 is placed on the central portion of the holding surface of the chuck table 41, and the annular dicing frame 3 is placed on the peripheral portion of the holding surface of the chuck table 41. Thereafter, suction means (not shown) is operated to hold the wafer 2 and the annular dicing frame 3 through the dicing tape 30 on the chuck table 41 under suction. Accordingly, the back side 2b of the wafer 2 held on the chuck table 41 is oriented upward. Thereafter, the chuck table 41 is rotated at 500 rpm, for example, and the grinding tool 42 is rotated at 1000 rpm, for example. At the same time, a feed mechanism (not shown) is operated to lower the grinding tool 42 until the grinding wheel 421 comes into contact with the back side 2b of the wafer 2. Thereafter, the grinding tool 42 is further fed downward by a predetermined amount. As a result, the back side 2b of the wafer 2 is ground to reduce the thickness of the wafer 2 to a predetermined thickness (e.g., 100 μm).

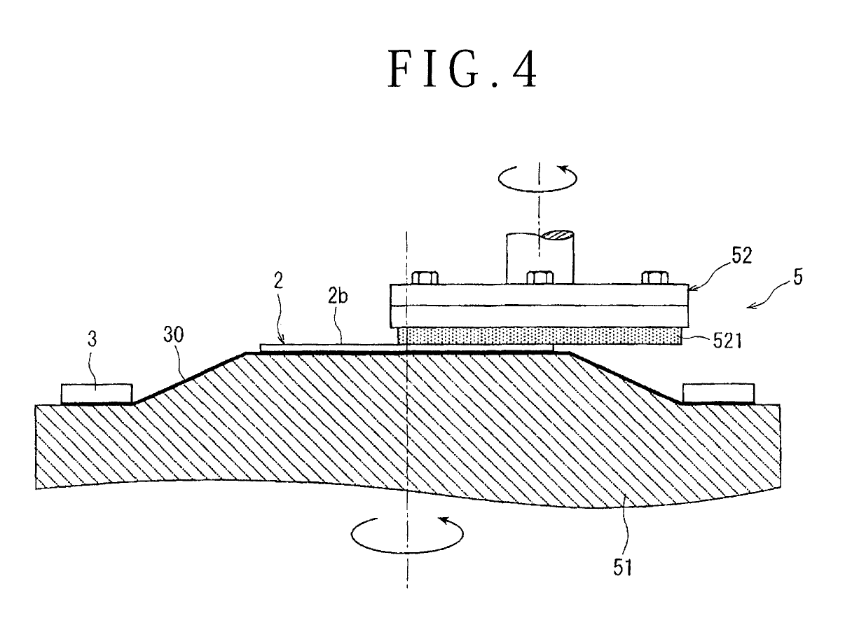

After performing the back grinding step mentioned above, a back polishing step is preferably performed in such a manner that the back side 2b of the wafer 2 is polished to remove grinding strain from the back side 2b and achieve mirror finish on the back side 2b as shown in FIG. 4. This back polishing step is performed by using a polishing apparatus 5 shown in FIG. 4. The polishing apparatus 5 shown in FIG. 4 includes a chuck table 51 for holding the wafer 2 and a polishing tool 52 having a polishing pad 521 for polishing the back side 2b of the wafer 2 held on the chuck table 51. The polishing pad 521 is composed of a soft member of felt or the like, abrasive grains of zirconium oxide or the like dispersed in the soft member, and a suitable bond for binding the abrasive grains. The central portion of the chuck table 51 adapted to hold the wafer 2 is higher in level than the peripheral portion adapted to hold the annular dicing frame 3.

The back polishing step using the polishing apparatus 5 is performed in the following manner. As shown in FIG. 4, the wafer 2 supported through the dicing tape 30 is placed on the holding surface of the chuck table 51 of the polishing apparatus 5 in the condition where the back side of the dicing tape 30 comes into contact with the holding surface of the chuck table 51. In this condition, the wafer 2 is placed on the central portion of the holding surface of the chuck table 51, and the annular dicing frame 3 is placed on the peripheral portion of the holding surface of the chuck table 51. Thereafter, suction means (not shown) is operated to hold the wafer 2 and the annular dicing frame 3 through the dicing tape 30 on the chuck table 51 under suction. Accordingly, the back side 2b of the wafer 2 held on the chuck table 51 is oriented upward. Thereafter, the chuck table 51 is rotated at 300 rpm, for example, and the polishing tool 52 is rotated at 6000 rpm, for example. At the same time, a feed mechanism (not shown) is operated to lower the polishing tool 52 until the polishing pad 521 comes into contact with the back side 2b of the wafer 2, thereby achieving mirror finish on the back side 2b of the wafer 2

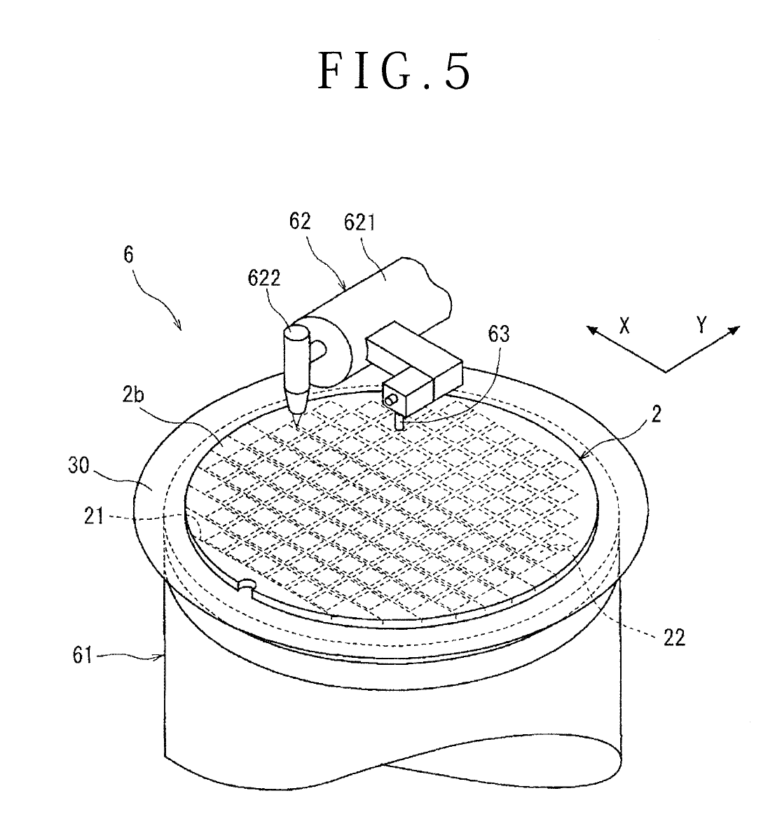

After performing the back polishing step mentioned above, a break start point forming step is performed in such a manner that a break start point is formed along each street 21 from the back side 2b of the wafer 2. As an example of this break start point forming step, a modified layer forming step will now be described. This modified layer forming step is performed in such a manner that a laser beam is applied to the wafer 2 along the streets 21 to thereby form a modified layer inside the wafer 2 along each street 21. This modified layer forming step is performed by using a laser processing apparatus 6 shown in FIG. 5. The laser processing apparatus 6 shown in FIG. 5 includes a chuck table 61 for holding the wafer 2, laser beam applying means 62 for applying a laser beam to the wafer 2 held on the chuck table 61, and imaging means 63 for imaging the wafer 2 held on the chuck table 61. The chuck table 61 is so configured as to hold the wafer 2 under suction. The chuck table 61 is movable both in a feeding direction shown by an arrow X in FIG. 5 by feeding means (not shown) and in an indexing direction shown by an arrow Y in FIG. 5 by indexing means (not shown).

The laser applying means 62 includes a cylindrical casing 621 extending in a substantially horizontal direction and focusing means 622 mounted on the front end of the casing 621 for focusing a pulsed laser beam. The imaging means 63 is mounted on the front end portion of the casing 621 of the laser beam applying means 62. The imaging means 63 includes an ordinary imaging device (CCD) for imaging the wafer 2 by using visible light, infrared light applying means for applying infrared light to the wafer 2, an optical system for capturing the infrared light applied to the wafer 2 by the infrared light applying means, and an imaging device (infrared CCD) for outputting an electrical signal corresponding to the infrared light captured by the optical system. An image signal output from the imaging means 63 is transmitted to control means (not shown).

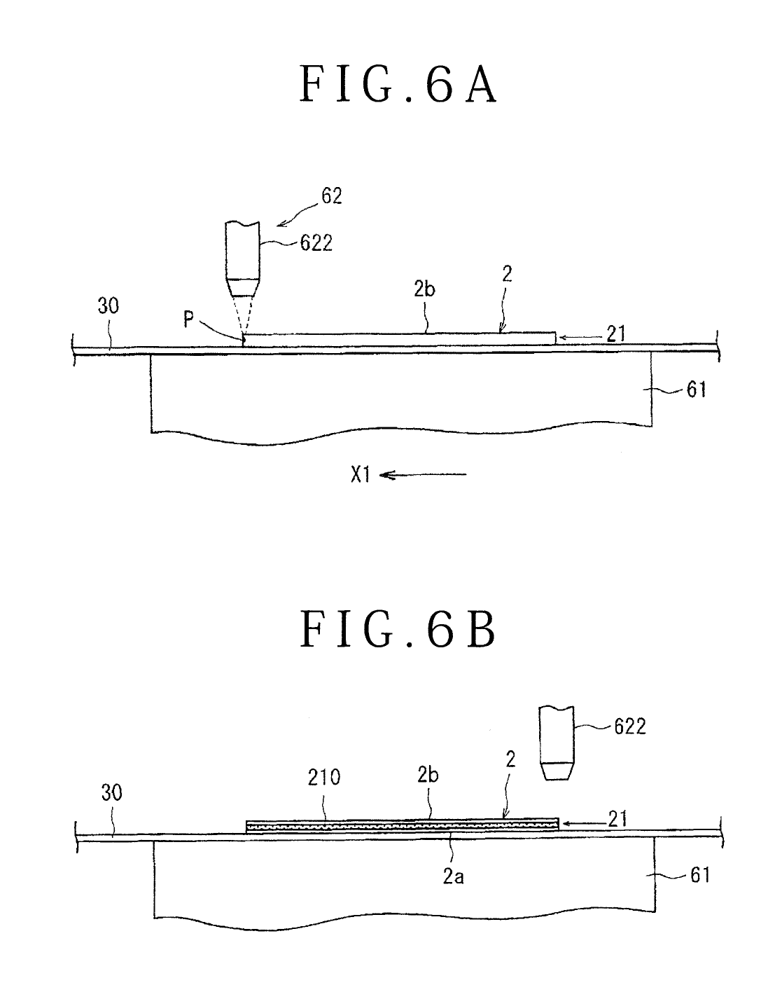

The above-described modified layer forming step using the laser processing apparatus 6 will now be described with reference to FIGS. 5, 6A, and 6B. In performing the modified layer forming step, the wafer 2 is first placed on the chuck table 61 of the laser processing apparatus 6 in the condition where the dicing tape 30 attached to the front side 2a of the wafer 2 comes into contact with the upper surface of the chuck table 61. Thereafter, suction means (not shown) is operated to hold the wafer 2 on the chuck table 61 under suction. Accordingly, the back side 2b of the wafer 2 held on the chuck table 61 is oriented upward. Thereafter, the chuck table 61 thus holding the wafer 2 is moved to a position directly below the imaging means 63 by the feeding means.

In the condition where the chuck table 61 is positioned directly below the imaging means 63, an alignment operation is performed by the imaging means 63 and the control means (not shown) to detect a subject area of the wafer 2 to be laser-processed. More specifically, the imaging means 63 and the control means perform image processing such as pattern matching for making the alignment of the streets 21 extending in a first direction on the wafer 2 and the focusing means 622 of the laser beam applying means 62 for applying the laser beam along the streets 21, thus performing the alignment of a laser beam applying position (alignment step). This alignment operation is performed similarly for the other streets 21 extending in a second direction perpendicular to the first direction mentioned above on the wafer 2. Although the front side 2a of the wafer 2 on which the streets 21 are formed is oriented downward, the streets 21 can be imaged from the back side 2b of the wafer 2 because the sapphire substrate constituting the wafer 2 is transparent. In the case that the wafer 2 is constituted of a silicon substrate which is not transparent, infrared light is applied from the infrared light applying means included in the imaging means 63 to the wafer 2, thereby imaging the streets 21 from the back side 2b of the wafer 2.

After performing the alignment step mentioned above, the chuck table 61 is moved to a laser beam applying area where the focusing means 622 of the laser beam applying means 62 is located as shown in FIG. 6A, thereby positioning one end (left end as viewed in FIG. 6A) of a predetermined one of the streets 21 extending in the first direction directly below the focusing means 622 of the laser beam applying means 62. In this condition, a pulsed laser beam having a transmission wavelength to the sapphire substrate is applied from the focusing means 622 to the wafer 2, and the chuck table 61 is moved in a direction shown by an arrow X1 in FIG. 6A at a predetermined feed speed. When the other end (right end as viewed in FIG. 6B) of the predetermined street 21 reaches the position directly below the focusing means 622 as shown in FIG. 6B, the application of the pulsed laser beam is stopped and the movement of the chuck table 61 is also stopped (modified layer forming step). In this modified layer forming step, the focal point P of the pulsed laser beam is set at the middle of the thickness of the wafer 2. In this preferred embodiment, the back side 2b of the wafer 2 has already been mirror-finished in the back polishing step, there is no possibility of irregular reflection of the laser beam on the back side 2b of the wafer 2, so that the focal point of the laser beam can be accurately set at a predetermined position inside the wafer 2. As a result, a modified layer 210 as a break start point is formed in the wafer 2 along the predetermined street 21 as shown in FIG. 6B. This modified layer 210 is formed as a molten and rehardened layer. The above-described modified layer forming step is performed along all of the streets 21 extending in the first and second directions on the wafer 2.

For example, the modified layer forming step mentioned above is performed under the following processing conditions.

Light source: LD pumped Q-switched Nd: YVO4 pulsed laser

Wavelength: 1064 nm

Average power: 1 W

Repetition frequency: 100 kHz

Focused spot diameter: φ1 μm

Work feed speed: 100 mm/sec

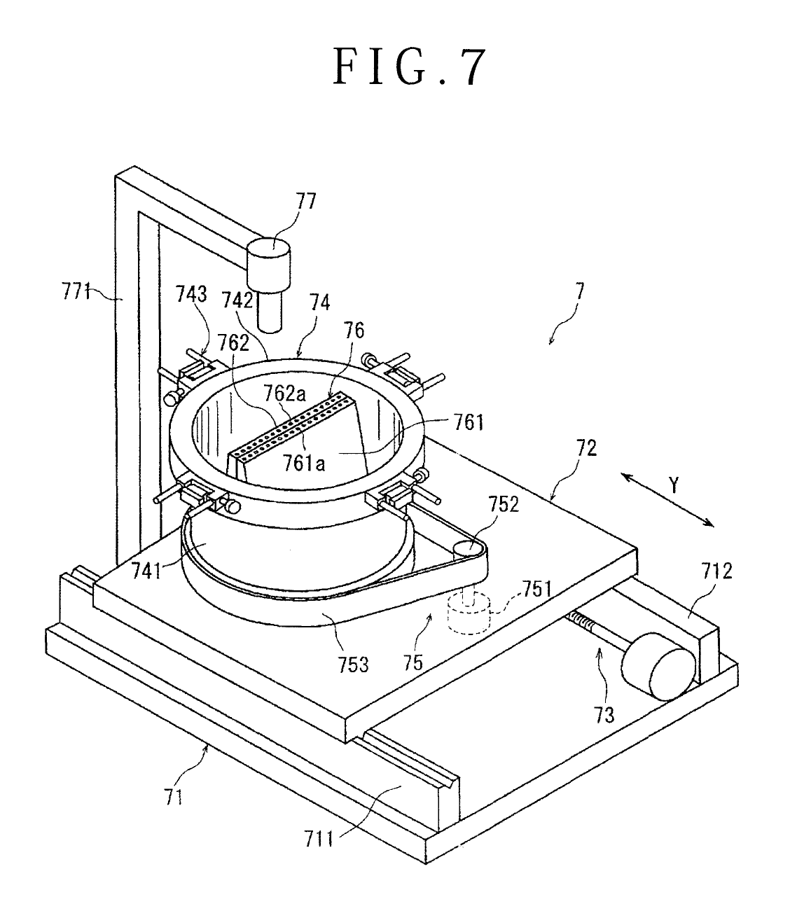

After thus finishing the modified layer forming step along all of the streets 21 extending in the first and second directions on the wafer 2 as an example of the break start point forming step, a wafer breaking step is performed in such a manner that an external force is applied to the wafer 2 to thereby break the wafer 2 along each street 21 where the break start point is formed, thereby dividing the wafer 2 into the individual devices 22. This wafer breaking step is performed by using a wafer breaking apparatus 7 shown in FIG. 7.

The wafer breaking apparatus 7 shown in FIG. 7 includes a base 71 and a moving table 72 provided on the base 71 so as to be movable in the direction shown by an arrow Y in FIG. 7. The base 71 is a rectangular platelike member, and a pair of parallel guide rails 711 and 712 are provided on the upper surface of the base 71 near the opposite side portions thereof so as to extend in the direction of the arrow Y. The moving table 72 is movably mounted on the two guide rails 711 and 712. The wafer breaking apparatus 7 further includes moving means 73 for moving the moving table 72 in the direction of the arrow Y. Frame holding means 74 for holding the annular dicing frame 3 is provided on the moving table 72. The frame holding means 74 includes a cylindrical body 741, an annular frame holding member 742 formed at the upper end of the cylindrical body 741, and a plurality of clamps 743 as fixing means provided on the outer circumference of the frame holding member 742. The annular dicing frame 3 is placed on the frame holding member 742 and fixed by the clamps 743. The wafer breaking apparatus 7 further includes rotating means 75 for rotating the frame holding means 74. The rotating means 75 includes a pulse motor 751 provided on the moving table 72, a pulley 752 mounted on the rotating shaft of the pulse motor 751, and an endless belt 753 wrapped between the pulley 752 and the cylindrical body 741. By operating the pulse motor 751, the frame holding means 74 is rotated through the pulley 752 and the endless belt 753.

The wafer breaking apparatus 7 further includes tension applying means 76 for applying a tensile force to the wafer 2 in a direction perpendicular to the streets 21 extending in a predetermined direction in the condition where the wafer 2 is supported through the dicing tape 30 to the annular dicing frame 3 held on the annular frame holding member 742. The tension applying means 76 is provided inside the annular frame holding member 742. The tension applying means 76 includes a first suction holding member 761 and a second suction holding member 762, wherein each of the first and second suction holding members 761 and 762 has a rectangular holding surface elongated in a direction perpendicular to the direction of the arrow Y in FIG. 7. The first suction holding member 761 is formed with a plurality of suction holes 761a, and the second suction holding member 762 is formed with a plurality of suction holes 762a. These plural suction holes 761a and 762a are connected to suction means (not shown). The first and second suction holding members 761 and 762 are individually movable in the direction of the arrow Y by moving means (not shown). The tension applying means 76 and the frame holding means 74 are relatively movable in the direction of the arrow Y.

The wafer breaking apparatus 7 further includes detecting means 77 for detecting the streets 21 of the wafer 2 supported through the dicing tape 30 to the annular dicing frame 3 held on the annular frame holding member 742. The detecting means 77 is mounted on an L-shaped support member 771 standing from the base 71. The detecting means 77 is constituted of an optical system, an imaging device (CCD), etc., and it is located above the tension applying means 76. The detecting means 77 functions to image the streets 21 of the wafer 2 supported through the dicing tape 30 to the dicing frame 3 held on the annular frame holding member 742 and to transmit an image signal as an electrical signal to control means (not shown).

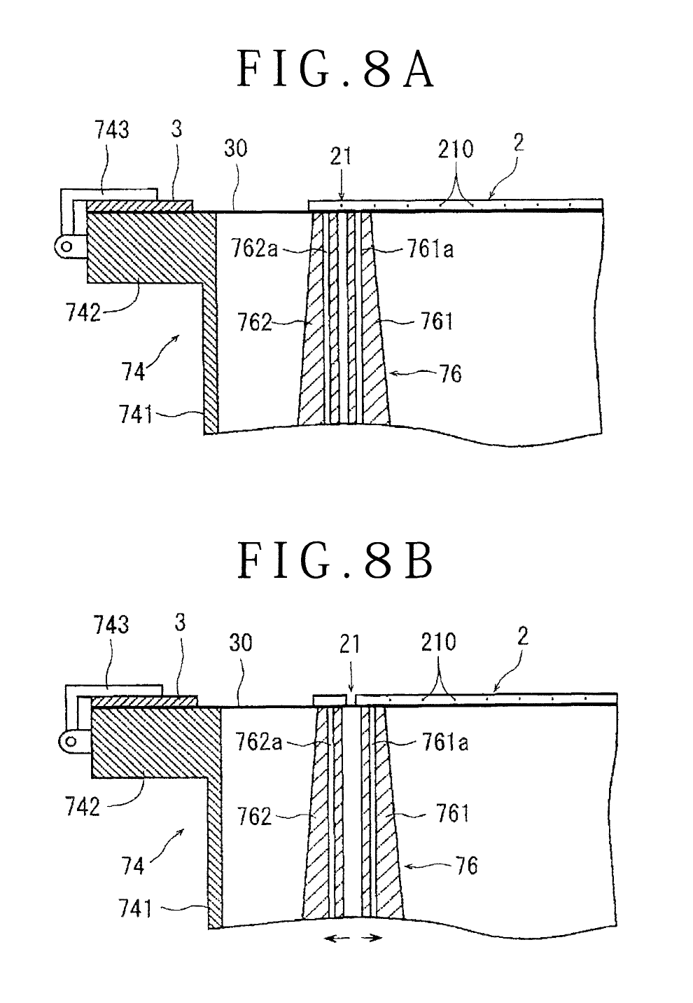

The wafer breaking step using the wafer breaking apparatus 7 mentioned above will now be described with reference to FIGS. 8A and 8B. The annular dicing frame 3 supporting the wafer 2 through the dicing tape 30 is placed on the frame holding member 742 and is next fixed to the frame holding member 742 by the clamps 743 as shown in FIG. 8A. Thereafter, the moving means 73 is operated to move the moving table 72 in the direction of the arrow Y shown in FIG. 7 so that a predetermined one of the streets 21 extending in the first direction perpendicular to the direction of the arrow Y (e.g., the leftmost street 21 as viewed in FIG. 8A) is positioned between the holding surface of the first suction holding member 761 of the tension applying means 76 and the holding surface of the second suction holding member 762 of the tension applying means 76 as shown in FIG. 8A. At this time, the predetermined street 21 is imaged by the detecting means 77 to position the holding surfaces of the first and second suction holding members 761 and 762 with respect to the predetermined street 21. Thereafter, the suction means not shown is operated to produce vacuum in the suction holes 761a and 762a, thereby holding the wafer 2 through the dicing tape 30 on the holding surfaces of the first and second suction holding members 761 and 762 (holding step).

After performing this holding step, the moving means for moving the tension applying means 76 is operated to move the first suction holding member 761 and the second suction holding member 762 in the opposite directions as shown in FIG. 8B. As a result, the predetermined street 21 positioned between the holding surface of the first suction holding member 761 and the holding surface of the second suction holding member 762 receives a tensile force in the direction of the arrow Y perpendicular to the direction of extension of the predetermined street 21, so that the wafer 2 is broken along this predetermined street 21 where the modified layer 210 is formed as the break start point (breaking step). In this breaking step, the dicing tape 30 is slightly stretched. The modified layer 210 is formed along each street 21 and the strength of the wafer 2 is reduced along each street 21. Accordingly, when the first and second suction holding members 761 and 762 holding the wafer 2 are moved in the opposite directions by a small amount of about 0.5 mm, the wafer 2 can be easily broken along the predetermined street 21 where the modified layer 210 is formed as the break start point.

After performing the breaking step of breaking the wafer 2 along the predetermined street 21 mentioned above, the suction holding of the wafer 2 by the first and second suction holding members 761 and 762 is canceled. Thereafter, the moving means 73 is operated again to move the moving table 72 in the direction of the arrow Y shown in FIG. 7 by an amount corresponding to the pitch of the streets 21, so that the next street 21 adjacent to the predetermined street 21 mentioned above is positioned between the holding surface of the first suction holding member 761 and the holding surface of the second suction holding member 762. Thereafter, the holding step and the breaking step are performed similarly.

After performing the holding step and the breaking step for all of the streets 21 extending in the first direction, the rotating means 75 is operated to 90° rotate the frame holding means 74. As a result, the wafer 2 held on the frame holding member 742 of the frame holding means 74 is also rotated 90°, so that the other streets 21 extending in the second direction perpendicular to the first direction become parallel to the holding surfaces of the first and second suction holding members 761 and 762. Thereafter, the holding step and the breaking step are performed similarly for all of the other streets 21 extending in the second direction, thereby dividing the wafer 2 into the individual devices 22.

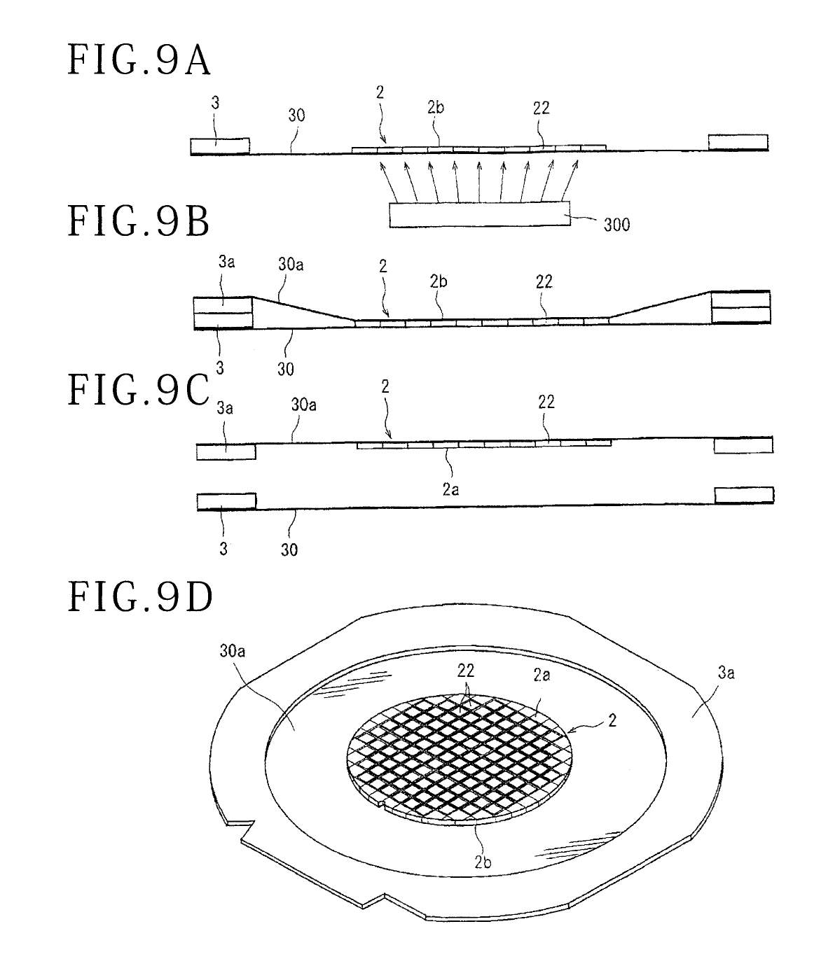

After performing the wafer breaking step mentioned above, a wafer transferring step is performed in such a manner that the back side 2b of the wafer 2 is attached to the front side of an adhesive tape 30a supported to an annular frame 3a and that the dicing tape 30 is next removed from the front side 2a of the wafer 2, thus transferring the wafer 2 from the dicing tape 30 to the adhesive tape 30a as shown in FIGS. 9A to 9D. First, as shown in FIG. 9A, ultraviolet radiation is applied from ultraviolet radiation applying means 300 to the dicing tape 30 supported to the dicing frame 3. At this time, the individual optical devices 22 divided from each other remain attached to the dicing tape 30 and maintain the form of the wafer 2. As a result, the adhesive layer of the dicing tape 30 is cured by the application of the ultraviolet radiation and the adhesive strength of the dicing tape 30 is therefore reduced. Thereafter, as shown in FIG. 9B, the front side (the lower surface as viewed in FIG. 9B) of the adhesive tape 30a supported to the annular frame 3a is attached to the back side 2b (the upper surface as viewed in FIG. 9B) of the wafer 2 attached to the dicing tape 30 supported to the dicing frame 3. Thereafter, as shown in FIG. 9C, the front side 2a of the wafer 2 (the individual optical devices 22 divided from each other) is removed from the dicing tape 30. At this time, the wafer 2 can be easily removed from the dicing tape 30 because the adhesive strength of the dicing tape 30 has been reduced by the application of the ultraviolet radiation in the step of FIG. 9A. Thereafter, the dicing frame 3 supporting the dicing tape 30 is discarded. As a result, the wafer 2 is transferred from the dicing tape 30 to the adhesive tape 30a in the condition where the wafer 2 has already been divided into the individual optical devices 22 and the front side 2a of the wafer 2 is oriented upward as shown in FIG. 9D.

In this manner, the wafer transferring step is performed after performing the back grinding step, the break start point forming step, and the wafer breaking step in the condition where the front side 2a of the wafer 2 is attached to the dicing tape 30 supported to the annular dicing frame 3 to thereby divide the wafer 2 into the individual devices 22. Accordingly, the wafer 2 can be transferred from the dicing tape 30 to the adhesive tape 30a supported to the annular frame 3a without cracking in the wafer 2, so that the front side 2a of the wafer 2 attached to the dicing tape 30 is exposed and the back side 2b of the wafer 2 is attached to the adhesive tape 30a. Accordingly, a continuity test can be performed for each device 22 in the condition where the wafer 2 divided into the individual devices 22 is attached to the adhesive tape 30a supported to the annular frame 3a.

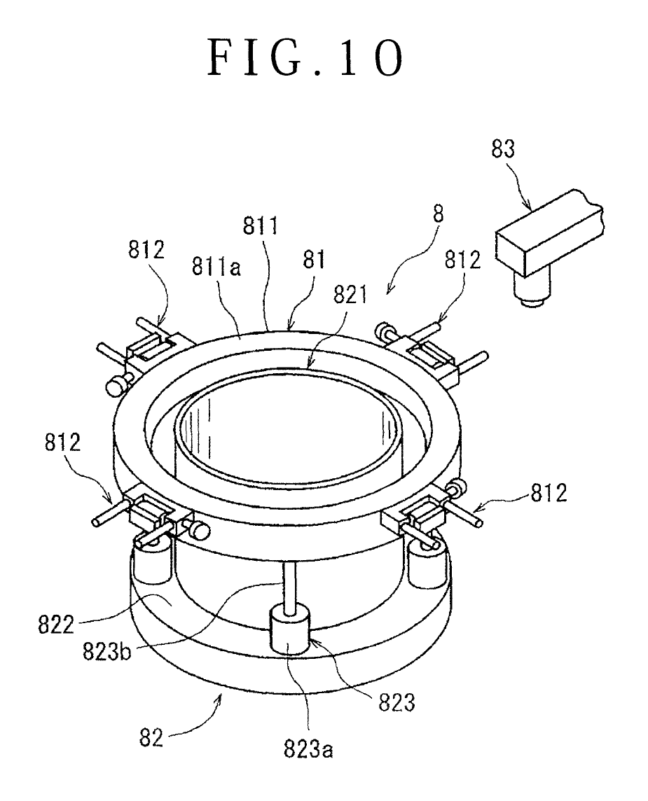

After performing the wafer transferring step mentioned above, a pickup step is performed in such a manner that the individual devices 22 divided from each other and attached to the adhesive tape 30a supported to the annular frame 3a are picked up from the adhesive tape 30a. This pickup step is performed by using a pickup apparatus 8 shown in FIG. 10. The pickup apparatus 8 shown in FIG. 10 includes frame holding means 81 for holding the annular frame 3a, tape expanding means 82 for expanding the adhesive tape 30a supported to the annular frame 3a held by the frame holding means 81, and a pickup collet 83. The frame holding means 81 includes an annular frame holding member 811 and a plurality of clamps 812 as fixing means provided on the outer circumference of the frame holding member 811. The upper surface of the frame holding member 811 functions as a mounting surface 811a for mounting the annular frame 3a thereon. The annular frame 3a mounted on the mounting surface 811a is fixed to the frame holding member 811 by the clamps 812. The frame holding means 81 is supported by the tape expanding means 82 so as to be vertically movable.

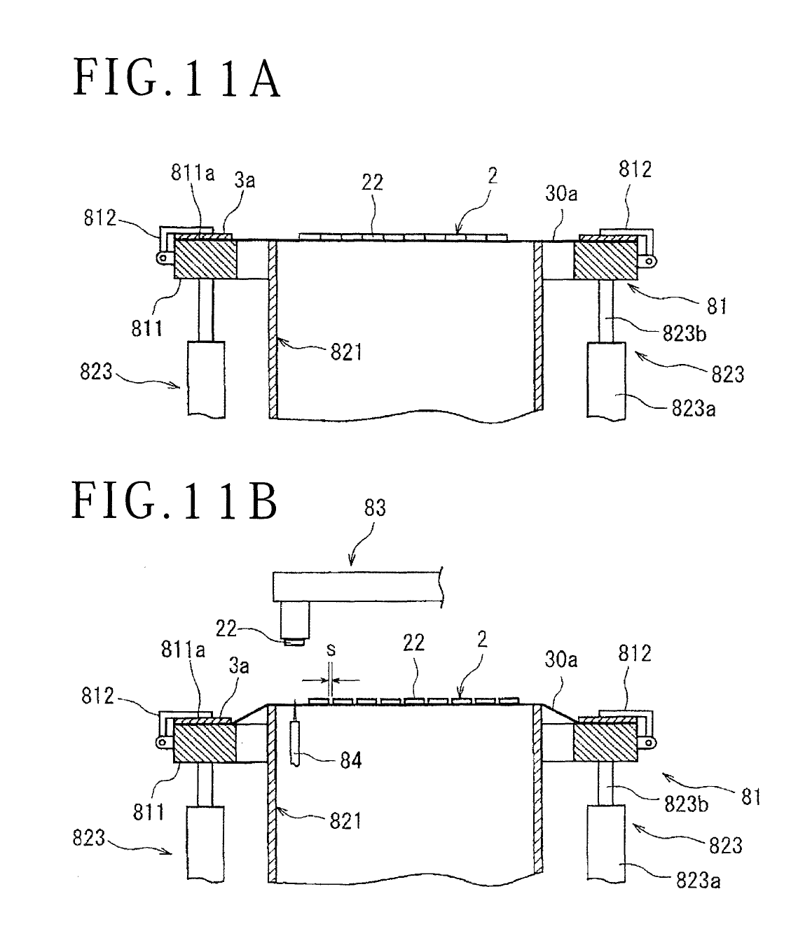

The tape expanding means 82 includes an expanding drum 821 provided inside of the annular frame holding member 811. The expanding drum 821 has an outer diameter smaller than the inner diameter of the annular frame 3a and an inner diameter larger than the outer diameter of the wafer 2 attached to the adhesive tape 30a supported to the annular frame 3a, wherein the wafer 2 has already been divided into the individual devices 22. The expanding drum 821 has a supporting flange 822 at the lower end of the drum 821. The tape expanding means 82 further includes supporting means 823 for vertically movably supporting the annular frame holding member 811. The supporting means 823 is composed of a plurality of air cylinders 823a provided on the supporting flange 822. Each air cylinder 823a is provided with a piston rod 823b connected to the lower surface of the annular frame holding member 811. The supporting means 823 composed of these plural air cylinders 823a functions to vertically move the annular frame holding member 811 so as to selectively take a reference position where the mounting surface 811a is substantially equal in height to the upper end of the expanding drum 821 as shown in FIG. 11A and an expansion position where the mounting surface 811a is lower in height than the upper end of the expanding drum 821 by a predetermined amount as shown in FIG. 11B.

The pickup step using the pickup apparatus 8 will now be described with reference to FIGS. 11A and 11B. As shown in FIG. 11A, the annular frame 3a supporting the wafer 2 (which has already been divided into the individual devices 22) through the adhesive tape 30a is mounted on the mounting surface 811a of the frame holding member 811 of the frame holding means 81 and fixed to the frame holding member 811 by the clamps 812 (frame holding step). At this time, the frame holding member 811 is set at the reference position shown in FIG. 11A. Thereafter, the air cylinders 823a as the supporting means 823 of the tape expanding means 82 are operated to lower the frame holding member 811 to the expansion position shown in FIG. 11B. Accordingly, the annular frame 3a fixed to the mounting surface 811a of the frame holding member 811 is also lowered, so that the adhesive tape 30a supported to the annular frame 3a comes into abutment against the upper end of the expanding drum 821 and is expanded as shown in FIG. 11B (tape expanding step):

The wafer 2 attached to the adhesive tape 30a has already been divided into the individual devices 22 along the streets 21. Accordingly, the spacing S between any adjacent ones of the individual devices 22 is increased by this tape expanding step as shown in FIG. 11B. Thereafter, the pickup collet 83 is operated to hold the front side (upper surface) of each device 22 under suction and peel off from the adhesive tape 30a as shown in FIG. 11B. At this time, each device 22 is pushed up by a push pin 84 from the lower side of the adhesive tape 30a as shown in FIG. 11B, so that each device 22 can be easily peeled off from the adhesive tape 30a. Since the back side of each device 22 is pushed up by the push pin 84, the damage to the front side of each device 22 by the push pin 84 can be prevented. In this pickup step, the spacing S between any adjacent ones of the individual devices 22 is increased, so that each device 22 can be easily picked up without the contact with its adjacent device 22. Further, since the front side (upper surface) of each device 22 is held under suction by the pickup collet 83 in this pickup step, it is not necessary to reverse each device 22 in the subsequent step.

While the specific preferred embodiment of the present invention has been described, it should be noted that the present invention is not limited to this preferred embodiment, but various modifications may be made without departing from the scope of the present invention. In the above preferred embodiment, the modified layer forming step is performed by applying a laser beam to the wafer along each street to thereby form a modified layer inside the wafer along each street as an example of the break start point forming step of forming a break start point along each street from the back side of the wafer. As a modification, the break start point forming step may be provided by a step of applying a laser beam having an absorption wavelength to the wafer along each street from the back side of the wafer to thereby form a laser processed groove as a break start point along each street. As another modification, the break start point forming step may be provided by a step of using a diamond scriber to form a scribe groove along each street from the back side of the wafer.

Further, in the above preferred embodiment, the wafer breaking step is performed by applying a tensile force to the wafer in a direction perpendicular to each street along which the modified layer is formed as the break start point, thereby breaking the wafer along each street. As a modification, the wafer breaking step may be provided by a step of applying a bending stress along each street where the strength of the wafer is reduced, thereby breaking the wafer along each street as disclosed in Japanese Patent Laid-Open Nos. 2006-107273 and 2006-128211, for example.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer processing method for dividing a wafer into individual devices along a plurality of crossing streets formed on the front side of said wafer, said individual devices being respectively formed in a plurality of regions partitioned by said streets, said wafer processing method comprising:
a wafer supporting step of attaching the front side of said wafer to a dicing tape supported to an annular dicing frame;
a back grinding step of grinding the back side of said wafer to reduce the thickness of said wafer to a predetermined thickness after performing said wafer supporting step;
a break start point forming step of forming a break start point along each street from the back side of said wafer after performing said back grinding step;
a wafer breaking step of applying an external force to said wafer to break said wafer along each street where said break start point is formed, thereby dividing said wafer into said individual devices after performing said break start point forming step;
a wafer transferring step of attaching the back side of said wafer to an adhesive tape supported to an annular frame and next peeling off said dicing tape from the front side of said wafer to remove the annular dicing frame after performing said wafer breaking step; and
a pickup step of peeling off and picking up each device from said adhesive tape after performing said wafer transferring step.

2. The wafer processing method according to claim 1, further comprising a back polishing step of polishing the back side of said wafer by using a polishing pad after performing said back grinding step and before performing said break start point forming step.
